(19) United States
(12) Patent Application Publication
(10) Pub. No.: US 2024/0371812 A1
(43) Pub. Date: Nov. 7, 2024

(54) ELECTRONIC PACKAGE AND A PACKAGING METHOD

(71) Applicant: STATS ChipPAC Pte. Ltd., Singapore (SG)

(72) Inventors: MyungHo JUNG, Gyeonggi-do (KR); BumRyul MAENG, Incheon (KR)

(21) Appl. No.: 18/655,254

(22) Filed: May 4, 2024

(30) Foreign Application Priority Data
May 6, 2023 (CN) 202310501203.8

(51) Int. Cl. H01L 23/00; H01L 21/683; H01L 23/31; H01L 25/065

(52) U.S. Cl. CPC H01L 24/16; H01L 21/6835; H01L 23/3107; H01L 24/11; H01L 24/14; H01L 25/0655; H01L 2224/11001; H01L 2224/11013; H01L 2224/11622; H01L 2224/1403; H01L 2224/14051; H01L 2224/16225; H01L 2924/1815

(57) ABSTRACT

An electronic package and a packaging method are provided. The packaging method comprises: forming on a carrier film a first photoresist pattern having multiple sets of first openings; filling in the multiple sets of first openings of the first photoresist pattern with a solder material to form multiple sets of solder bumps; forming on the first photoresist pattern a second photoresist pattern having multiple second openings each exposing a set of the sets of solder bumps; attaching one or more electronic components to the set of solder bumps in each of the second openings; filling in the second openings of the second photoresist pattern with an encapsulant material to form an encapsulant layer that at least partially encapsulates the one or more electronic components in each of the second openings; and removing the second photoresist pattern from the carrier film to form multiple electronic packages.

### TECHNICAL FIELD

The present application generally relates to semiconductor manufacturing technologies, and more particularly, to an electronic package and a wafer level packaging method.

### BACKGROUND

The semiconductor industry is constantly faced with complex integration challenges as consumers want their electronics to be smaller, faster and higher performance with more and more functionalities packed into a single device. In order to satisfy such demands, wafer level packaging processes have been commonly used, which can reduce the area of a package, and manufacture packages in batches, etc. Therefore, the manufacturing cost can be reduced by utilizing wafer level packaging processes. However, the conventional wafer level packaging processes may need to be further simplified to provide lower handling risks, fewer quality problems, which may occur in the back-end process.

Therefore, a need exists for an improved wafer level packaging method.

### SUMMARY

An objective of the present application is to provide a simplified wafer level packaging method.

According to an aspect of the present application, there is provided a packaging method, comprising: forming on a carrier film a first photoresist pattern having multiple sets of first openings; filling in the multiple sets of first openings of the first photoresist pattern with a solder material to form multiple sets of solder bumps; forming on the first photoresist pattern a second photoresist pattern having multiple second openings each exposing a set of the sets of solder bumps; attaching one or more electronic components to the set of solder bumps in each of the second openings; filling in the second openings of the second photoresist pattern with an encapsulant material to form an encapsulant layer that at least partially encapsulates the one or more electronic components in each of the second openings; and removing the second photoresist pattern from the carrier film to form multiple electronic packages.

According to another aspect of the present application, there is provided an electronic package formed using the aforesaid packaging method.

According to a further aspect of the present application, there is provided an electronic package, comprising: an encapsulant mold having a front surface and a rear surface; one or more electronic components encapsulated within the encapsulant mold and exposed from the rear surface of the encapsulant mold; and a set of solder bumps attached to the rear surface and electrically connected with the one or more electronic components.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF THE DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1A illustrates three electronic packages formed on a carrier film according to an embodiment of the present application.

FIG. 1B illustrates three electronic packages formed on a carrier film according to another embodiment of the present application.

FIGS. 2A to 2I illustrate a method for packaging one or more electronic components according to an embodiment of the present application.

FIGS. 3A to 3H illustrate a method for packaging a semiconductor die according to an embodiment of the present application.

FIG. 4A illustrates an electronic package according to an embodiment of the present application.

FIG. 4B illustrates an electronic package according to another embodiment of the present application.

The same reference numbers will be used throughout the drawings to refer to the same or like parts.

### DETAILED DESCRIPTION OF THE PREFERRED EMBODIMENTS

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

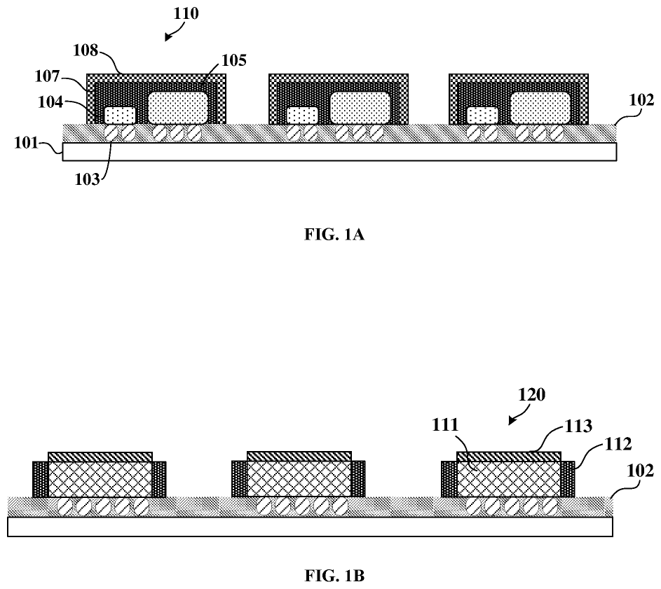

FIG. 1A illustrates three electronic packages 110 formed on a carrier film 101 according to an embodiment of the present application. The electronic packages 110 are formed on the carrier film 101 in a batch, which may have the same structure and composition, and can be detached from the carrier film 101 later if desired. In some embodiments, one or more electronic components such as electronic components 104 and 105 can be encapsulated into an electronic package 110 on the carrier film 101. However, the electronic packages 110 may have different compositions in some embodiments. For example, different numbers of electronic components and different types of electronic components may be encapsulated within respective electronic packages 110.

In some embodiments, the carrier film 101 can be made of a polyimide film, however, films of other materials may be used as the carrier film 101. Furthermore, the carrier film 101 may be supported by a base carrier such as a metal panel or a wafer panel during the entire packaging process. An adhesive material may be coated on a bottom surface of the carrier film 101 to attach the carrier film 101 firmly onto the base carrier during the packaging process. The carrier film 101 may be detached from the base carrier after the packaging process, thereby the base carrier may be reused for other batches of packaging processes.

Referring to FIG. 1A, a first photoresist pattern 102 is formed on the carrier film 101. In the embodiment, the first photoresist pattern 102 has multiple sets of first openings each being filled with a solder material, so as to form multiple sets of solder bumps 103. Each set of solder bumps 103 may be used for a package 110. It can be appreciated that the size, shape and pitch of the solder bumps 103 may change with the first photoresist pattern 102. For example, as top surfaces of the solder bumps 103 are generally flush with a top surface of the first photoresist pattern 102, the height of the solder bumps 103 is substantially the same as the thickness of the first photoresist pattern 102. Thus, a thicker first photoresist pattern 102 may result in higher solder bumps 103, and a thinner first photoresist pattern 102 may result in lower solder bumps 103. Also, the sets of first openings of the first photoresist pattern 102 may be formed using a lithographic process which can provide sufficient fine pitches and linewidths, for example, less than 20 um or even less. In that case, the pitch of solder bumps in each set of solder bumps 103 can be accurately controlled and can be as smaller as desired. Furthermore, as the first openings are preformed in the first photoresist pattern 102 using a mask, the layout and shape of the first openings, i.e., the layout and the shape of the solder bumps 103, can be modified or configured as desired, which are generally independent from the subsequent solder filling process. In some embodiments, the solder material can be filled in the first openings of the first photoresist pattern 102 using a printing process. Since the solder material is filled only within the first openings and does not cover the top surface of the first photoresist pattern 102, the solder bumps 103 formed are generally free of solder bridges, which can avoid potential short issues between adjacent solder bumps 103. In some embodiments, the solder bumps 103 may be formed by first depositing sufficient solder materials on the first photoresist pattern 102 (including in the first openings) and then removing the excess amount of solder materials which are over the top surface of the first photoresist pattern 102 but not filled in the first openings. In this way, the first openings can be well filled to avoid potential pseudo soldering issues.

The multiple sets of solder bumps 103 are used to attach one or more electronic components, such as passive electronic component including resistors, capacitors, and inductors, and active electronic components. For example, the active electronic components may include a digital signal processor (DSP), a microcontroller, a microprocessor, a network processor, a power management processor, an audio processor, a video processor, an RF circuit, a wireless baseband system on chip (SoC) processor, a sensor, a memory controller, a memory device, an application specific integrated circuit (ASIC), etc. In some embodiments, the electronic components may be small IC chips that contain different well-defined subsets of functionalities, and allow to integrate a variety of different architectures, different process nodes, and even dedicated silicon blocks or intellectual property (IP) blocks from different foundries into a single package. The electronic components may have conductive patterns such as contact pads on their respective bottom surfaces, which can be connected to the solder bumps in the first photoresist pattern 102 upon being aligned with each other.

As shown in FIG. 1A, each set of electronic components 104 and 105 are encapsulated in an encapsulant layer 107 to form an electronic package 110. The encapsulant layer 107 can be polymer composite material, such as epoxy resin, epoxy acrylate, or any suitable polymer with or without filler. The encapsulant layer 107 is non-conductive, provides structural support, and environmentally protects the electronic components from external elements and contaminants. In some embodiments, the encapsulant layer 107 may have a height that is greater than heights of the electronic components 104 and 105 to ensure that they can be fully encapsulated. In some other embodiments, the encapsulant layer 107 may have a height that is substantially equal to a height of the electronic component 105 (which is the largest one of the electronic components) to expose a top surface of the electronic component 105, for example, when it is desired to connect certain conductive patterns on the top surface of the electronic component 105.

In some embodiments, the encapsulant layer 107 is formed over and besides the electronic components 104 and 105. In some other embodiments, the encapsulant layer 107 may be formed besides the electronic components 104 and 105 but not over them or over a portion of them. In some other embodiments, the encapsulant layer 107 may be formed over the electronic components 104 and 105 but not fully surrounding them, i.e., the electronic components may have one or more their lateral surfaces exposed from the encapsulant layer 107. It can be appreciated that more flexibility in the design of the package can be realized. In some embodiments, a shielding layer 108 is formed on the encapsulant layer 107. The shielding layer 108 can be formed by spray coating, plating, sputtering, or any other suitable metal deposition process. The shielding layer 108 can be formed from copper, aluminum, iron, or any other suitable material for EMI shielding.

FIG. 1B illustrates three electronic packages 120 formed on a carrier film 101 according to another embodiment of the present application. Different from the electronic packages 110 shown in FIG. 1A, each of the electronic packages 120 has only one electronic component 111 partially encapsulated by an encapsulant layer 112. The electronic component 111 may be a semiconductor die or a smaller semiconductor package. Furthermore, the encapsulant layer 112 is formed besides the electronic component 111 and exposes a top surface of the electronic component 111. In some embodiments, a dielectric material 113 is formed on top of the electronic component 111 to cover the top surface of the electronic component 111. In some embodiments, the dielectric material 113 is a high thermal conductive epoxy molding compound.

It can be seen from FIG. 1A and FIG. 1B, once the electronic packages are detached from the carrier films, they are separated pieces or units that are independent from each other. As such, no singulation process is required for such electronic packages.

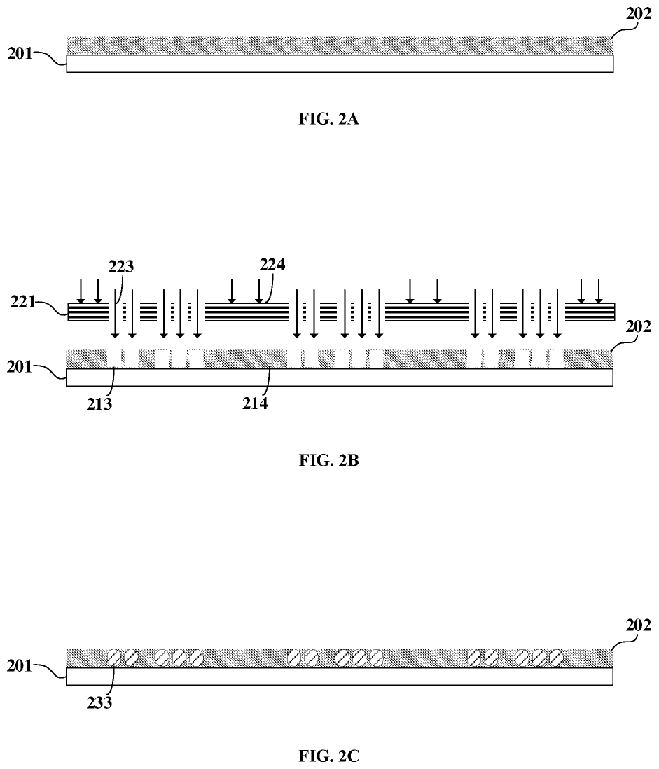

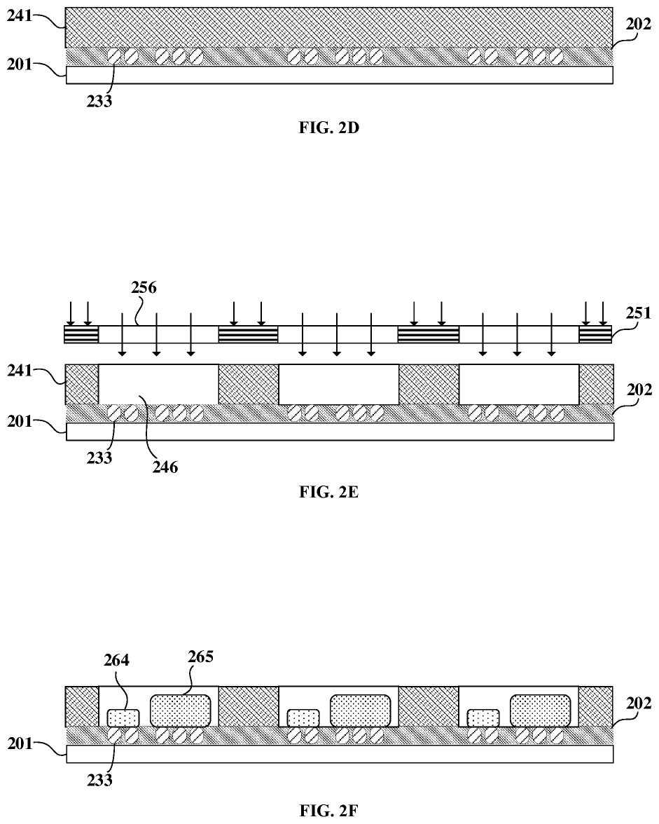

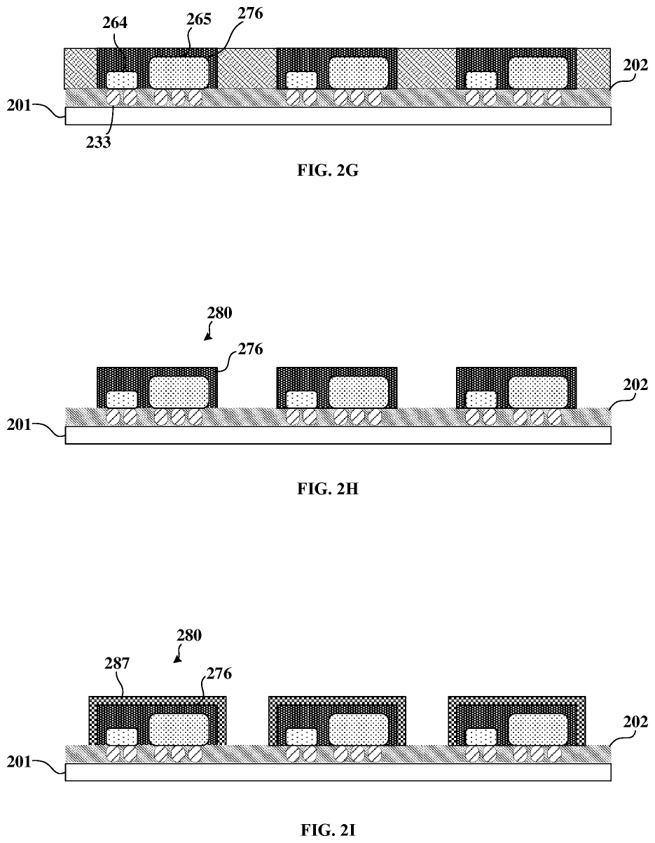

FIGS. 2A to 2I illustrate a method for packaging one or more electronic components according to an embodiment of the present application. Upon completion of the steps of the method, the packaged electronic components form an electronic package. The method can be used to form the electronic packages shown in FIG. 1A, for example.

As illustrated in FIG. 2A, a carrier film 201 may be provided, which may be attached onto a base carrier such as a wafer panel. A first photoresist layer 202 is coated on the carrier film 201. In some embodiments, the first photoresist layer 202 can be either a positive photoresist or a negative photoresist, with slightly different subsequent processes and photomasks. In the embodiment, the first photoresist layer 202 is a positive photoresist which may be dissolvable to a developing solution after being exposed.

As shown in FIG. 2B, a first photomask 221 is placed above the carrier film 201, which has non-transparent regions 224 and transparent regions 223 such as windows or openings that allow light transmission therethrough. Light radiation such as an ultraviolet light can be emitted towards to the carrier film 201 through the first photomask 221. As such, the first photoresist layer 202 on the carrier film 201 can be selectively exposed, to form two portions, i.e., exposed portions and non-exposed portions 214. The exposed portions can be further dissolved in the developing solution, so as to form multiple sets of first openings 213.

Afterwards, as illustrated in FIG. 2C, a solder material can be filled in the multiple sets of the first openings, to form multiple sets of solder bumps 233. The height of the solder bumps 233 is substantially the same as the thickness of the first photoresist 202. Accordingly, by adjusting the thickness of the first photoresist 202, one can easily change the height of the solder bumps 233. Similarly, one can also change the pattern of the first photoresist 202, i.e., changing the size and/or shape of the non-transparent regions and transparent regions of the first photomask, to adjust the shape and pitch of the solder bumps 233, thereby obtaining solder bumps 233 that are free of solder bridges.

Next, a second photoresist layer 241 is further formed on the carrier film 201 and above the solder bumps 233 and the remaining portions of the first photoresist layer 202, as shown in FIG. 2D. The second photoresist layer 241 may, upon being patterned, define various regions for forming respective electronic packages, which will be elaborated below in details.

Next, as illustrated in FIG. 2E, a second photomask 251 can be used to pattern the second photoresist layer 241, similar as the patterning of the first photoresist layer 202 shown in FIG. 2B. In particular, light radiation may be emitted toward the carrier film 201 through transparent regions 256 of the second photomask 251, expose at multiple positions of the second photoresist 241. In the embodiment, the second photoresist layer 241 is also a positive photoresist. The second photoresist layer 241 can be further developed by a developing solution, to remove the exposed portions of the second photoresist layer 241, leaving multiple second openings 246 therein. Each of the second opening 246 exposes a set of the sets of the solder bumps 233. Similar to the solder bumps 233, the size and shape of the second openings 246 can be controlled by the size and pattern of second photoresist 241. In some embodiments, at least two of the second openings 246 may have different sizes or shapes. That is to say, different electronic components can be packaged simultaneously using the method according to some embodiments of the present application. In some other embodiments, at least two of the second openings 246 may have the same size and shape.

Next, as illustrated in FIG. 2F, one or more electronic components, such as passive electronic components 264 and active electronic components 265, are attached to the set of solder bumps 233 exposed in each of the second opening 246. After the electronic components 264 and 265 are attached, an encapsulant material may be filled in each of the second openings 246 to form an encapsulant layer 276 that at least partially encapsulates the one or more electronic components in the second opening, as shown in FIG. 2G. In some embodiments, the encapsulant layer 276 is formed over and besides the electronic components 264 and 265 in each of the second openings 246. In some embodiments, the encapsulant layer 276 is formed besides the electronic components 264 and 265 in each of the second openings and exposes a top surface of at least one of the electronic components 264 and 265. In some embodiments, the top surface of the electronic components may be covered with a dielectric material. In some embodiments, the dielectric material is a high thermal conductive epoxy molding compound.

In some embodiments, alignment signs or marks may be formed in the first photoresist pattern 202 to facilitate the alignment between the electronic components 264 and 265 and the solder bumps 233 thereunder. In some other embodiments, the base carrier and the carrier film 201 and the first photoresist pattern 202 can all be light transparent, such that the alignment between solder bumps 233 and the electronic components such as the electronic components 264 and 265 can be observed from a position under the base carrier and the carrier film 201. Also, an adhesive material may be applied on the first photoresist pattern 202 or on the bottom surfaces of the electronic components 264 and 265 to avoid undesired movement of the electronic components during the subsequent packaging process.

After that, as illustrated in FIG. 2H, the remaining second photoresist layer on the first photoresist layer 202 can be removed off the carrier film 201, leaving the multiple encapsulated electronic packages 280 on the first photoresist layer 202. In this way, the whole carrier film 201 including all the electronic packages 280 thereon may be used for further processing. In some embodiments, the first photoresist layer 202 and the second photoresist layer may be of two different photoresists such that the second photoresist layer can be removed off while the first photoresist layer 202 can be maintained on the carrier film. In some other embodiments, the first and second photoresist layers can be of the same material if both of them can be removed simultaneously with the same developing solution. In some embodiments, a shielding layer 287 can be formed on each of the encapsulant layers 276, as shown in FIG. 2I. In some embodiments, the remaining first photoresist layer 202 can be removed off the carrier film 201, thus detaching the electronic packages 280 from the carrier film 201.

It can be appreciated that the method shown in FIG. 2A to 2I provides a simplified wafer level packaging method, wherein the bonding and encapsulation process are all conducted on a single carrier film. No separate process such as solder bumping forming, and EMI loading is required. With fewer steps of packaging method is required, it is more likely to reduce thermal and/or mechanical stress risk, thereby improving the overall quality of the electronic packages.

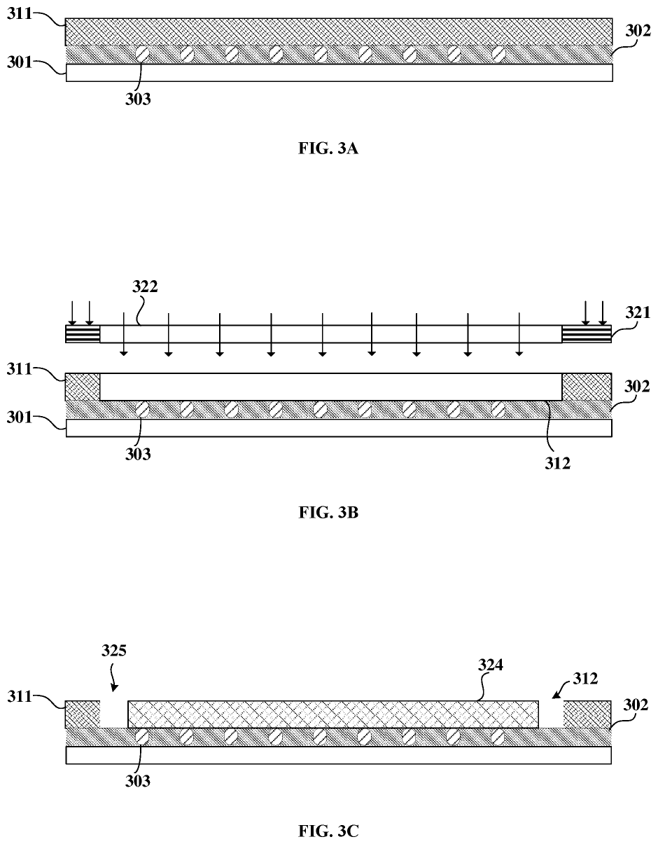

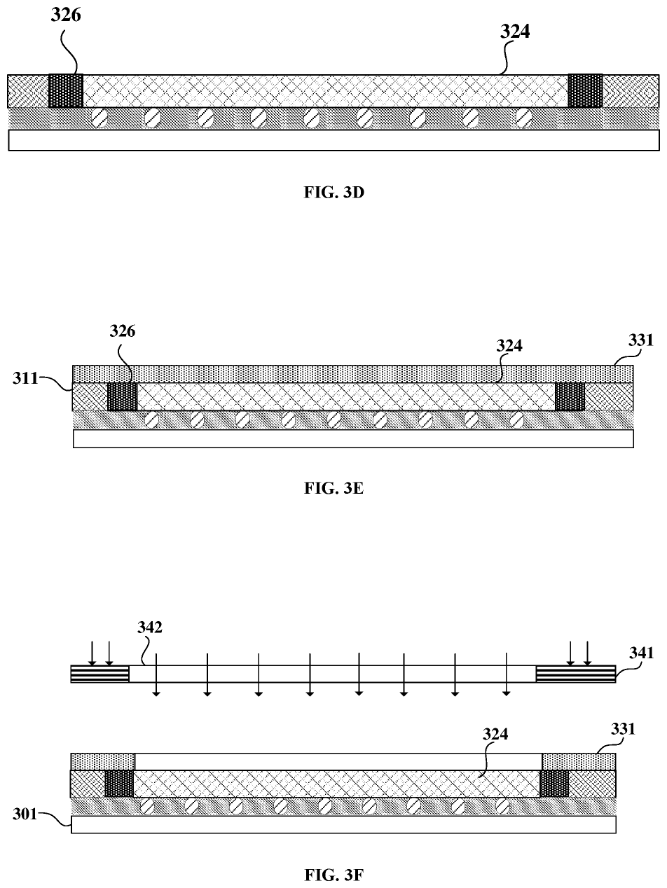

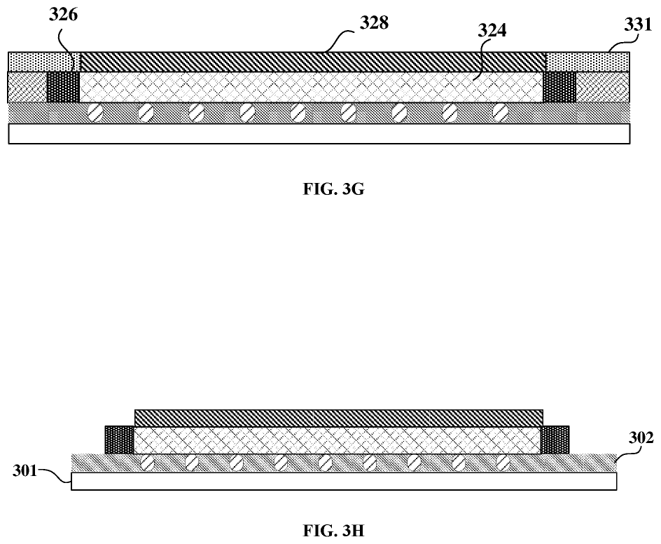

FIGS. 3A to 3H illustrate a method for packaging a semiconductor die according to an embodiment of the present application. The method can be used to form the electronic packages shown in FIG. 1B, for example.

As shown in FIG. 3A, a first photoresist pattern 302 with a set of solder bumps 303 may be provided, wherein the first photoresist pattern 302 may be formed on a carrier film 301. It can be appreciated although only one set of solder bumps 303 are shown in FIG. 3A, multiple sets of solder bumps can be formed in the first photoresist pattern 302 to form multiple electronic packages simultaneously, i.e., wafer level packaging where packages are formed in a batch. A second photoresist layer 311 is coated on the first photoresist pattern 302. In some embodiments, the second photoresist layer 311 can be either a positive photoresist or a negative photoresist, with slightly different subsequent processes and photomasks.

Next, as shown in FIG. 3B, a second photomask 321 is placed above the carrier film 301. Light radiation may be emitted toward the carrier film 301 through transparent regions 322 of the second photomask 321, exposing at multiple positions of the second photoresist layer 311. The second photoresist layer 311 can be further developed by a developing solution, to remove the exposed portions of the second photoresist layer 311, leaving multiple second openings 312 in the second photoresist layer 311. That is to say, the second photoresist layer 311 is patterned as the second photoresist pattern. Each of the second openings 312 may expose a set of the solder bumps 303. In some embodiments, at least two of the second openings 311 may have different sizes or shapes. In some other embodiments, at least two of the second openings 311 may have the same size and shape.

Next, as illustrated in FIG. 3C, a semiconductor die 324 is attached to the solder bumps 303 in one of the second openings 312, leaving some blank space 325 between the semiconductor die 324 and sidewalls of the second opening 312. In some embodiments, the height of the semiconductor die 324 is substantially the same as the thickness of the second photoresist pattern 311. Then, the blank space is filled with an encapsulant material forming a side mold 326 as shown in FIG. 3D.

After that, as illustrated in FIG. 3E, a third photoresist layer 331 is coated on the second photoresist pattern 311, the side mold 326 and the semiconductor die 324. Then, as shown in FIG. 3F, similar to the patterning of the first photoresist layer in FIG. 3B, a third photomask 341 is placed above the carrier film 301, wherein a transparent region 342 of the third photomask 341 is aligned with the semiconductor die 324. In some embodiments, the transparent region 342 has the same size and shape as a top surface of the semiconductor die 324. Light radiation may be emitted toward the carrier film 301 through the transparent regions 342 of the third photomask 341, thereby exposing a portion of the third photoresist layer 331 which is corresponding to the top surface of the semiconductor die 324. The third photoresist layer 331 can be further developed by a developing solution, to remove the exposed portion of the third photoresist layer 331, leaving a third opening exposing the top surface of the semiconductor die 324.

Next, a dielectric material 328 is filled within the third opening in the third photoresist pattern 331 to cover the top surface of the semiconductor die 324, as is shown in FIG. 3G. In some embodiments, the dielectric material 328 is a high thermal conductive epoxy molding compound. As illustrated in FIG. 3H, the remaining third photoresist layer can be removed off the carrier film 301, leaving the encapsulated semiconductor die on the first photoresists 302. In some embodiments, the remaining first photoresists 302 can be removed off the carrier film 301, thus the encapsulated semiconductor die can be detached from the carrier film 301.

FIG. 4A illustrates an electronic package 420 according to an embodiment of the present application.

As shown in FIG. 4A, the electronic package 420 includes an encapsulant mold 416 having a front surface 417 and a rear surface 418. One or more electronic components, such as a passive electronic component 404 and an active electronic component 405, are encapsulated within the encapsulant mold 416. The electronic components are exposed from the rear surface 418 of the encapsulant mold 416. A set of solder bumps 403 are attached to the rear surface 418 and electrically connected with the electronic components 404 and 405. In some embodiments, a shield layer 427 is formed over the encapsulant mold 416. In an example, the electronic package 420 may be detached from a carrier film like the carrier film 101 shown in FIG. 1A.

FIG. 4B illustrates an electronic package 440 according to an embodiment of the present application.

As shown in FIG. 4B, the electronic package 440 also includes an encapsulant mold 416 having a front surface 417 and a rear surface 418. The encapsulant mold 416 encapsulates a semiconductor die 406 on its lateral surfaces. The semiconductor die 406 is exposed both from the front surface 417 and the rear surface 418 of the encapsulant mold 416. A set of solder bumps 403 are attached to the rear surface 418 and electrically connected with the semiconductor die 406. At the front surface 417, a dielectric material 419 covers a surface of the semiconductor die 406 exposed from the front surface of the encapsulant mold 416. In some embodiments, the dielectric material 419 has the same size and shape as the top of the semiconductor die 406. In an example, the electronic package 440 may be detached from a carrier film like the carrier film 101 shown in FIG. 1B.

The discussion herein included numerous illustrative figures that showed various portions of an electronic package and a packaging method. For illustrative clarity, such figures did not show all aspects of each example assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

What is claimed is:

1. A packaging method, comprising
forming on a carrier film a first photoresist pattern having multiple sets of first openings;
filling in the multiple sets of first openings of the first photoresist pattern with a solder material to form multiple sets of solder bumps;
forming on the first photoresist pattern a second photoresist pattern having multiple second openings each exposing a set of the sets of solder bumps;
attaching one or more electronic components to the set of solder bumps in each of the second openings;
filling in the second openings of the second photoresist pattern with an encapsulant material to form an encapsulant layer that at least partially encapsulates the one or more electronic components in each of the second openings; and
removing the second photoresist pattern from the carrier film to form multiple electronic packages.

2. The method of claim 1, before removing the second photoresist pattern from the carrier film, the method further comprising:
forming a shielding layer on each of the encapsulant layers.

3. The method of claim 1, after removing the second photoresist pattern from the carrier film, the method further comprising:
detaching the electronic packages from the carrier film.

4. The method of claim 1, wherein at least two of the second openings have different sizes or shapes.

5. The method of claim 1, wherein at least two of the second openings have the same size and shape.

6. The method of claim 1, wherein the carrier film is an adhesive film attached onto a carrier.

7. The method of claim 1, wherein the encapsulant layer is formed over and besides the one or more electronic components in each of the second openings.

8. The method of claim 1, wherein encapsulant layer is formed besides the one or more electronic components in each of the second openings and exposes a top surface of at least one of the one or more electronic components.

9. The method of claim 1, wherein the one or more electronic components comprises a semiconductor die, and after filing in the second openings of the second photoresist pattern with an encapsulant material the method further comprises:
forming on the second photoresist pattern a third photoresist pattern having a third opening, wherein the third opening exposes a top surface of the semiconductor die; and
forming in the third opening a dielectric material to cover the exposed top surface of the semiconductor die.

10. The method of claim 9, wherein the dielectric material is a high thermal conductive epoxy molding compound.

11. The method of claim 9, wherein the third opening has a same size and shape as the semiconductor die.

12. An electronic package formed using the packaging method according to any one of claims 1 to 11.

13. An electronic package, comprising:
an encapsulant mold having a front surface and a rear surface;
one or more electronic components encapsulated within the encapsulant mold and exposed from the rear surface of the encapsulant mold; and
a set of solder bumps attached to the rear surface and electrically connected with the one or more electronic components.

14. The electronic package of claim 13, further comprising:
a shielding layer formed over the encapsulant mold.

15. The electronic package of claim 13, wherein the one or more electronic components comprises a semiconductor die, and the semiconductor die is further exposed from the front surface of the encapsulant mold, and wherein the electronic package further comprises:
a dielectric material covering a surface of the semiconductor die exposed from the front surface of the encapsulant mold.

16. The electronic packages of claim 15, wherein the dielectric material is a high thermal conductive epoxy molding compound.
